(19) United States
(12) Patent Application Publication
(10) Pub. No.: US 2021/0359183 A1
(43) Pub. Date: Nov. 18, 2021

(54) OPTOELECTRONIC SEMICONDUCTOR DEVICE AND METHOD FOR PRODUCING AN OPTOELECTRONIC SEMICONDUCTOR DEVICE

(71) Applicant: OSRAM Opto Semiconductors GmbH, Regensburg (DE)

(72) Inventors: Lay Sin KHOO, Tanjung Bungah, Penang (MY); Choon Keat OR, Ayer Itam, Penang (MY); Choon Sim ONG, Gelugor, Penang (MY); Wan Leng LIM, George Town, Penang (MY); Keng Chong LIM, George Town, Penang (MY); Choo Kean LIM, Gelugor, Penang (MY)

(21) Appl. No.: 17/262,628

(22) PCT Filed: Aug. 2, 2018
(86) PCT No.: PCT/EP2018/071055

§ 371 Date: Jan. 22, 2021

(51) Int. Cl. H01L 33/62; H01L 33/50; H01L 33/00; H01L 25/075

(52) U.S. Cl. CPC H01L 33/62; H01L 33/502; H01L 2933/0066; H01L 25/0753; H01L 33/005

(57) ABSTRACT

An optoelectronic semiconductor device includes a substrate with a first main side and a second main side. A plurality of light-emitting semiconductor chips is distributed over the first main side and over the second main side. A molding compound encloses the light-emitting semiconductor chips in a lateral direction. The molding compound levels with the light-emitting semiconductor chips in a direction away from the substrate. The molding compound has a top side facing away from the substrate. A plurality of planar electrical interconnects run on the top side and electrically connects the light-emitting semiconductor chips on their radiation exit sides facing away from the substrate.

An optoelectronic semiconductor device is provided. Further, a method for producing such an optoelectronic semiconductor device is also provided.

An object to be achieved is to provide an optoelectronic semiconductor device that can emit light on both main sides with high efficiency.

This object is achieved inter alia by an optoelectronic semiconductor device and by a method having the features of the independent claims. Preferred further developments are the subject-matter of the dependent claims.

In particular, an optoelectronic semiconductor device is provided that comprises a substrate. Light-emitting semiconductor chips are applied to both main sides of the substrate. This is possible in particular because of a molding compound that surrounds the light-emitting semiconductor chip, wherein planar electrical interconnects are applied on the molding compound to electrically contact the light-emitting semiconductor chips.

According to at least one embodiment, the optoelectronic semiconductor device comprises a substrate. The substrate has a first main side and a second main side. The first main side is opposite the second main side. For example, the substrate is a circuit board like a printed circuit board or a metal core board. In particular, the substrate can be of multilayer fashion, for example with a plurality of ceramic and metallic layers.

According to at least one embodiment, the optoelectronic semiconductor device comprises a plurality of light-emitting semiconductor chips. For example, the light-emitting semiconductor chips are light-emitting diode chips, LED chips for short. In particular, each one of the light-emitting semiconductor chips comprises a semiconductor layer sequence to produce light by means of electroluminescence.

According to at least one embodiment, the semiconductor layer sequence is based on a III-V compound semiconductor material. The semiconductor material is for example a nitride compound semiconductor material such as AlₙIn₁₋ₙ₋ₘGaₘN or a phosphide compound semiconductor material such as AlₙIn₁₋ₙ₋ₘGaₘP or also an arsenide compound semiconductor material such as AlₙIn₁₋ₙ₋ₘGaₘAs, wherein in each case 0≤n≤1, 0≤m≤1 and n+m≤1 applies. The semiconductor layer sequence may comprise dopants and additional constituents. For simplicity's sake, however, only the essential constituents of the crystal lattice of the semiconductor layer sequence are indicated, i.e. Al, As, Ga, In, N or P, even if these may in part be replaced and/or supplemented by small quantities of further substances.

The semiconductor layer sequence is particularly preferably based on the AlInGaN material system. In particular, the light-emitting semiconductor chips are designed to emit blue light.

According to at least one embodiment, the light-emitting semiconductor chips are distributed over the first main side and over the second main side. Preferably, the same number of light-emitting semiconductor chips is present on the first main side and on the second main side. As an alternative, there can be more light-emitting semiconductor chips on the first main side than on the second main side or vice versa.

According to at least one embodiment, the optoelectronic semiconductor device comprises one or more than one molding compound. The at least one molding compound encloses the light-emitting semiconductor chips in a lateral direction. Preferably, each one of the light-emitting semiconductor chips is completely surrounded by the respective molding compound seen in top view onto the respective main side of the substrate. It is possible for the molding compound to be reflective for the light generated in the light-emitting semiconductor chips during operation of the optoelectronic semiconductor device. In particular, the molding compound is of a white material.

According to at least one embodiment, the at least one molding compound has at least one top side facing away from the substrate. In particular, each molding compound has exactly one top side. Preferably, the respective top side is of planar fashion.

According to at least one embodiment, the respective top side levels with the respective light-emitting semiconductor chips in a direction away from the substrate. That is, the molding compound can terminate flush with the light-emitting semiconductor chips in a direction away from the substrate. Hence, the thickness of the molding compound can be equal or approximately equal to a height of the light-emitting semiconductor chips.

According to at least one embodiment, the optoelectronic semiconductor device comprises a plurality of planar electrical interconnects. The planar electrical interconnects run partly or completely on the at least one top side of the molding compound. Thus, a main direction of extent of the planar electrical interconnects can be in parallel with the main sides of the substrate. By means of the planar electrical interconnects, the light-emitting semiconductor chips are electrically connected, in particular on their radiation exit sides that face away from the substrate.

In at least one embodiment, the optoelectronic semiconductor device comprises a substrate with a first main side and a second main side. A plurality of light-emitting semiconductor chips is distributed over the first main side as well as over the second main side. At least one molding compound encloses the light-emitting semiconductor chips in a lateral direction. The at least one molding compound levels with the light-emitting semiconductor chips in a direction away from the substrate, the at least one molding compound has at least one top side facing away from the substrate. A plurality of planar electrical interconnects run at least partly on the at least one top side and electrically connects the light-emitting semiconductor chips on their radiation exit sides facing away from the substrate.

Conventionally, filament LED stripes are produced by means of die attach and wire bonding technology. Thus, the LED chips are placed only on one side of a substrate and the rear side of the substrate acts as a heat dissipation area. With this concept, it is not possible to mount the light-emitting diode chips on two opposite sides of the substrate because of heat dissipation issues.

The optoelectronic semiconductor device described here is in particular based on a planar interconnect process as an alternative to conventional wire bonding for electrically contacting the LED chips in a filament stripe. With planar interconnect technology, it is possible to produce a dual-sided LED emitter in particular for LED filaments. This also addresses the issue concerning the heat dissipation when a plurality of LED chips is mounted on the substrate.

Thus, with the optoelectronic semiconductor device described here, a dual-sided LED emitter for use as a filament is enabled. This maximizes the emission intensity in a single product without heat dissipation problems through a PCB substrate. Further, a simplified process by producing dual-sided LED emitters with a single flow process is possible. Long production cycle times due to a wire bonding process can be eliminated. A compact electrical connection by means of planar interconnection technology can be used to produce a compact product. In particular, mechanically flexible substrates can be applied in a reel-to-reel concept. The optoelectronic semiconductor devices can also be used, for example, for LED displays having a mirror image-like basic configuration.

According to at least one embodiment, the optoelectronic semiconductor device is fashioned as a filament. This means, in particular, that a length of the optoelectronic semiconductor device exceeds a width thereof by at least a factor of 3 or by at least a factor of 5 or by at least a factor of 10. Thus, the optoelectronic semiconductor device can be configured as a stripe. Such optoelectronic semiconductor devices can be used as back illumination in displays or, preferably, as a replacement for filaments in conventional lightbulbs. Thus, luminaires can be created that have the overall shape of a lightbulb but are based on LED technology.

According to at least one embodiment, the optoelectronic semiconductor device comprises electrical terminal connection surfaces. The electrical terminal connection surfaces are configured to externally electrically contact the optoelectronic semiconductor device. For example, the terminal connection surfaces are to connect the optoelectronic semiconductor device by means of soldering, electrical conductive films or also by clamping.

According to at least one embodiment, the electrical terminal connection surfaces are located solely at one end of the substrate. As an alternative, the terminal connection surfaces can be located solely at two opposing ends of the substrate. Thus, an intermediate section of the substrate can be free of the terminal connection surfaces. Preferably, the terminal connection surfaces are applied at the first main side and/or at the second main side of the substrate.

According to at least one embodiment, at least one of the electrical terminal connection surfaces is arranged on the first main side and at least one of the electrical terminal connection surfaces is arranged on the second main side. The number of terminal connection surfaces on the first main side is preferably equal to the number of terminal connection surfaces on the second main side. Preferably, there is exactly one or there are exactly two terminal connection surfaces on the first and on the second main side. In particular, on each main side there is a terminal connection surface for an anode contact and for a cathode contact.

According to at least one embodiment, the substrate comprises electrical connection areas. The electrical connection areas are located on the first main side as well as on the second main side. The light-emitting semiconductor chips are electrically and mechanically mounted on the connection areas. An electrical and also mechanical connection of the light-emitting semiconductor chips to the connection areas is done, for example, by means of soldering or by means of electrically conductive adhesives.

According to at least one embodiment, the substrate comprises internal electrical conductor tracks. These conductor tracks run to the connection areas. By means of these conductor tracks, the connection areas can be electrically connected in series or also in parallel. Preferably, the internal electrical conductor tracks are not accessible from an exterior of the semiconductor device. The internal electrical conductor tracks can be limited to an interior of the substrate. That is, the internal electrical conductor tracks may be covered all around by a material of the substrate in addition to the electrical terminal connection surfaces. As an alternative, the internal electrical conductor tracks can be free of a material of the substrate at lateral sides of the substrate. In addition, the light-emitting semiconductor chips can be arranged distant from the internal electrical conductor tracks.

According to at least one embodiment, the optoelectronic semiconductor device comprises electrical through connections. The through connections run through the at least one molding compound. By means of the through connections, an electrical connection between the connection areas and the corresponding planar electrical interconnects is realized. For example, the electrical through connections are formed by dummy chips or via chips or also by metallizations. In the case of metallizations, the through connections can be hollow structures like a cylinder wall, or could also be formed like a full cylinder, and thus could be free of voids or cavities.

According to at least one embodiment, some or all of the light-emitting semiconductor chips are electrically connected in parallel. In particular, there is exactly one electrical parallel connection on the first main side and exactly one electrical parallel connection on the second main side. That is, all light-emitting semiconductor chips on the first main side could be electrically connected in parallel and also all light-emitting semiconductor chips on the second main side could be electrically connected in parallel. As an alternative, there could be one or more series connections. For example of all light-emitting semiconductor chips on the first main side and of all light-emitting semiconductor chips on the second main side could be arranged in an electrical series connection, respectively. If there is a plurality of electrical parallel connections and/or of electrical serial connections, these parallel connections or series connections may be electrically connectable independently of one another.

According to at least one embodiment, the optoelectronic semiconductor device comprises two or more than two molding compounds. In the case of exactly two molding compounds, each molding compound is preferably limited to one of the main sides of the substrate. Thus, there can be a molding compound for each main side of the substrate. The molding compound on the respective main side preferably encloses all of the light-emitting semiconductor chips and optionally all of the electrical through connections on the respective main side.

According to at least one embodiment, the optoelectronic semiconductor device comprises exactly one molding compound. Preferably, the molding compound continuously extends to the first and to the second main side. Thus, seen in a cross-section, the molding compound can completely surround and enclose the substrate on the two main sides. Thus, all of the light-emitting semiconductor chips can be enclosed in the same molding compound.

According to at least one embodiment, the optoelectronic semiconductor device further comprises one or more than one potting compound. The at least one potting compound preferably covers the light-emitting semiconductor chips and the at least one molding compound. In particular, the semiconductor chips and the molding compound can completely be covered by the potting compound. As is the case for the molding compound, the potting compound can be limited to one of the main sides of the substrate. In this case, there can be a plurality of potting compounds. As an alternative, the just one potting compound completely encases the substrate when seen in a cross-section.

According to at least one embodiment, the at least one potting compound comprises a phosphor or a phosphor mixture. By means of the at least one phosphor together with the light-emitting semiconductor chips, in particular white light can be produced. Otherwise, light of colors other than white can also be produced.

The phosphor preferably comprises at least one of the following luminescent materials: Eu²⁺-doped nitrides such as (Ca,Sr)AlSiN₃:Eu²⁺, Sr(Ca,Sr)Si₂Al₂N₆:Eu²⁺, (Sr,Ca)AlSiN₃*Si₂N₂O:Eu²⁺, (Ca,Ba,Sr)₂Si₅N₈:Eu²⁺, (Sr,Ca)[LiAl₃N₄]:Eu²⁺; garnets from the general system (Gd,Lu,Tb,Y)₃(Al,Ga,D)₅(O,X)₁₂:RE with X=halide, N or divalent element, D=tri- or tetravalent element and RE=rare earth metals such as Lu₃(Al₁₋ₓGaₓ)₅O₁₂:Ce³⁺, Y₃(Al₁₋ₓGaₓ)₅O₁₂:Ce³⁺; Eu²⁺-doped sulfides such as (Ca,Sr,Ba)S:Eu²⁺; Eu²⁺-doped SiONs such as (Ba,Sr,Ca)Si₂O₂N₂:Eu²⁺; SiAlONs for instance from the system LiₓM_{y}Ln_{z}Si₁₂₋₍ₘ₊ₙ₎Al(m+n)OₙN₁₆₋ₙ; beta-SiAlONs from the system Si₆₋ₓAl_{z}O_{y}N_{8-y}:RE_{z}; nitrido-orthosilicates such as AE₂₋ₓ₋ₐREₓEuₐSiO₄₋ₓNₓ, AE₂₋ₓ₋ₐREₓEuₐSi_{1-y}O_{4-x-2y}Nₓ with RE=rare earth metal and AE=alkaline earth metal; orthosilicates such as (Ba,Sr,Ca,Mg)₂SiO₄:Eu²⁺; chlorosilicates such as Ca₈Mg(SiO₄)₄Cl₂:Eu²⁺; chlorophosphates such as (Sr,Ba,Ca,Mg)₁₀(PO₄)₆Cl₂:Eu²⁺; BAM luminescent materials from the BaO—MgO—Al₂O₃ system such as BaMgAl₁₀O₁₇:Eu²⁺; halophosphates such as M₅(PO₄)₃(Cl,F):(Eu²⁺,Sb³⁺,Mn²⁺); SCAP luminescent materials such as (Sr,Ba,Ca)₅(PO₄)₃Cl:Eu²⁺. Quantum dots may moreover also be introduced as converter material. Quantum dots in the form of nanocrystalline materials which contain a group II-VI compound and/or a group III-V compound and/or a group IV-VI compound and/or metal nanocrystals, are preferred in this case.

According to at least one embodiment, the substrate has a mean thermal conductivity of at least 25 W/(m·K) or of at least 50 W/(m·K) or of at least 80 W/(m·K). For example, the substrate is based on at least one ceramic or on at least one metal or on at least one semiconductor material.

According to at least one embodiment, a thickness of the substrate is at least 0.2 mm or at least 0.4 mm. As an alternative or in addition, the mean thickness of the substrate is at most 2 mm or at most 1 mm or at most 0.7 mm. Thus, the substrate can be comparably thin.

According to at least one embodiment, the optoelectronic semiconductor device is mechanically flexible. This is particularly enabled by using a mechanically flexible substrate and by having a molding compound that can be mechanically flexible, too. Thus, the light-emitting semiconductor chips can be of rigid fashion and deformations are limited or essentially limited to the substrate, the molding compound and the conductor tracks and optionally also to the potting compound. In particular, a radius of curvature that can reversibly be reached is less than 2 cm or less than 1 cm.

Moreover, a production method is provided. By means of the production method, an optoelectronic semiconductor device as indicated in connection with one or more of the above-stated embodiments is produced. Features of the method are therefore also disclosed for the optoelectronic semiconductor device and vice versa.

In at least one embodiment, the method is for producing an optoelectronic semiconductor device. The method comprises the following steps, in particular in the stated order:
providing the substrate,
attaching the respective light-emitting semiconductor chips at the first main side,
attaching the respective light-emitting semiconductor chips at the second main side,
molding the molding compound, and
applying the planar electrical interconnects.

According to at least one embodiment, the molding compound is formed by foil-assisted molding, FAM for short.

According to at least one embodiment, between the steps of attaching the respective light-emitting semiconductor chips to the first main side and to the second main side, in a snap curing step the light-emitting semiconductor chips at the first main side are preliminarily connected to the first main side. The snap curing is done, for example, by means of an epoxy resin that can be cured by means of infrared radiation, by means of ultraviolet radiation or by means of comparably low temperatures, for example at a temperature of at most 125° C. or of at most 100° C.

According to at least one embodiment, the electrical through connections are produced by means of a lithography method. Thus, the electrical through connections are preferably produced after molding the molding compound, in particular if the through connections are formed by metallizations.

According to at least one embodiment, the electrical connection areas and the electrical terminal connection surfaces are produced with the help of a dielectric layer build-up, in particular by means of resist deposition and exposure. Metallizations used for the contact surfaces are produced, for example, by using a seed layer that can be produced by evaporation or by sputtering, followed by an electroplating process.

An optoelectronic semiconductor device and a method described herein are explained in greater detail below by way of exemplary embodiments with reference to the drawings. Elements which are the same in the figures are indicated by the same reference signs. The relationships between the elements are not shown to scale, however, but rather individual elements may be shown exaggeratedly large to assist in understanding.

In the figures:

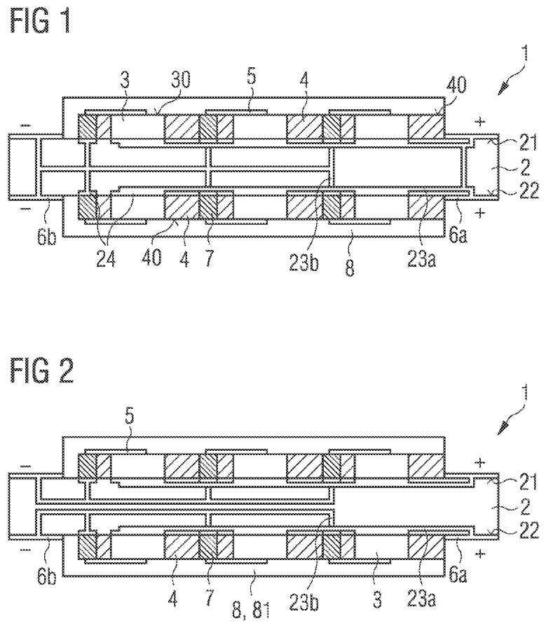

FIGS. 1 to 2 show sectional representations along a longitudinal direction of exemplary embodiments of optoelectronic semiconductor devices described here;

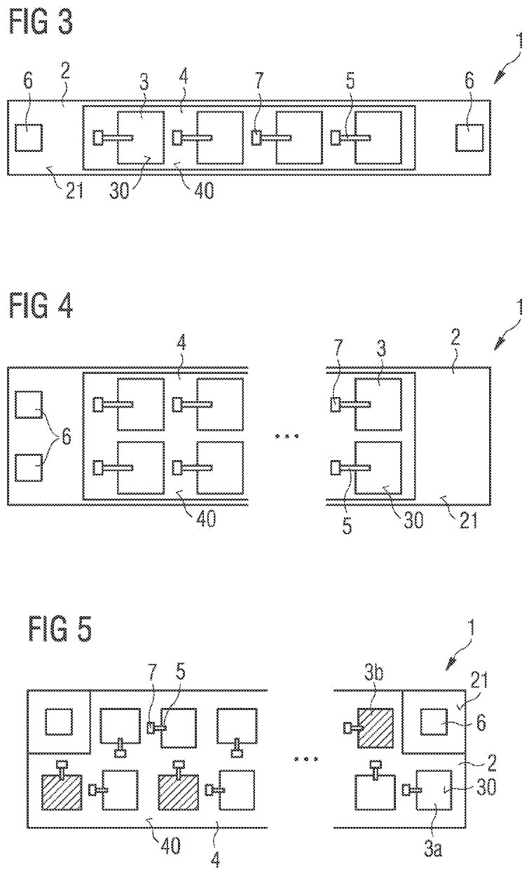

FIGS. 3 to 5 show top views of exemplary embodiments of optoelectronic semiconductor devices described here;

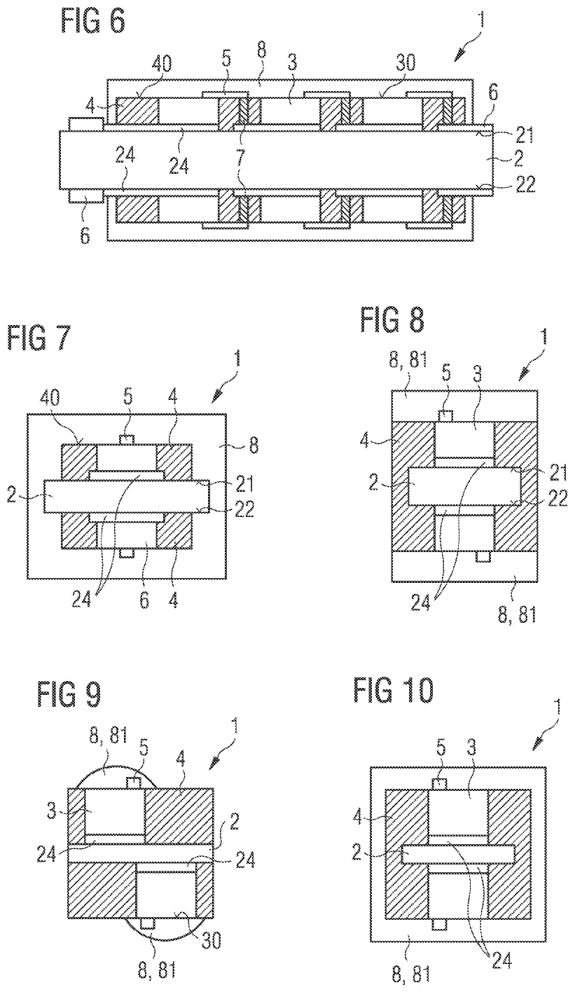

FIG. 6 shows a sectional representation of an exemplary embodiment of an optoelectronic semiconductor device described here, and

FIGS. 7 to 10 show sectional representations in a cross direction of exemplary embodiments of optoelectronic semiconductor devices described here.

FIG. 1 shows an exemplary embodiment of an optoelectronic semiconductor device 1. The semiconductor device 1 comprises a substrate 2. The substrate 2 has a first main side 21 and a second main side 22. Within the substrate 2, there are first internal electrical conductor tracks 23a and second internal electrical conductor tracks 23b. Both conductor tracks 23a, 23b run towards electrical contact areas 24 and also to electrical terminal connections surfaces 6a, 6b. The terminal connection surfaces 6a, 6b are to externally electrically contact the optoelectronic semiconductor device 1, for example by soldering or clamping.

In particular, there are two terminal connection surfaces 6a for an anode contact, one on each one of the main sides 21, 22. The same is true for the terminal connection surfaces 6b which can be fashioned as cathode contacts. As an option, the respective terminal connection surfaces 6a, 6b of the same type and located on the first main side 21 and on the second main side 22 can be electrically connected directly to one another by means of the internal conductor tracks 23a, 23b. Thus, the respective terminal connection surfaces 6a, 6b of the same type can be electrically short-circuited.

Moreover, the optoelectronic semiconductor device 1 comprises a plurality of light-emitting semiconductor chips 3. Preferably, the light-emitting semiconductor chips 3 are LED chips. For example, the light-emitting semiconductor chips 3 are blue-emitting LED chips. Otherwise, there can be different kinds of light-emitting semiconductor chips 3 that produce, for example, red light as well as green light and blue light and, as an option, also yellow light. The light-emitting semiconductor chips 3 are mounted on the electrical connection areas 24.

Further, there is a molding compound 4. The molding compound 4 laterally encloses the light-emitting diode chips 3 all around. In a direction away from the substrate 2, the molding compound 4 terminates flush with the light-emitting semiconductor chips 3. Thus, a top side 40 of the molding compound 4 can lie in the same plane as radiation exit sides 30 of the light-emitting diode chips 3. The light exit sides 30 are remote from the substrate 2.

For example, the molding compound 4 is of a reflective, white material. In particular, the molding compound 4 is made of a silicone that is filled with reflective particles which can be made of titanium dioxide, for example. Otherwise, the molding compound 4 can also be of an absorbing material like a resin filled with carbon black. However, preferably the molding compound 4 is highly reflective to the light generated in the light-emitting semiconductor chips 3 during operation of the semiconductor device 1.

Moreover, there is a plurality of electrical through connections 7. The through connections 7 run through the molding compound 4 and end at the substrate 2 at the connection areas 24. The through connections 7 are made of dummy chips or of metallizations, for example. Preferably, a height of the through connections 7 is equal or similar to the height of the light-emitting semiconductor chips 3.

An electrical connection to the light exit sides 30 of the light-emitting semiconductor chips 3 is made by means of planar electrical interconnects 5. The planar interconnects 5 run from the respective through connections 7 to the assigned light-emitting semiconductor chip 3. There can be a one-to-one assignment between the connections 7, the interconnects 5 and the respective semiconductor chips 3. Preferably, the through connections 7 are made of one or a plurality of metallic layers.

As the light-emitting semiconductor chips 3 are located on both main sides 21, 22, the semiconductor device 1 can efficiently emit light on both main sides 21, 22. The substrate 2 is by far longer than broad so that the semiconductor device 1 can be an LED filament. The overall semiconductor device 1 might be of mechanical flexible fashion because of the possibly flexible substrate 2 and the molding compound 4.

Other than shown in FIG. 1 it is also possible that there is a single electrical through connection for a plurality of light-emitting semiconductor chips 3. From such a through connection, the planar interconnects may run in a star-like fashion, for example. As an option, the optoelectronic semiconductor device 1 can also comprise further semiconductor chips like protection devices against damage because of electrostatic discharge, called ESD. Moreover, there can be memory devices or integrated circuits to address the light-emitting diode chips 3. Such optional further components are not shown in the exemplary embodiments to simplify the drawings.

According to FIG. 1, there are just three light-emitting semiconductor chips 3 on each main side 21, 22 of the substrate 2. Preferably, there is a much larger number of semiconductor chips on the respective main side 21, 22, for example at least 10 or at least 20 or at least 30 and/or at most 120 or at most 80 of the light-emitting semiconductor chips 3. This applies for all other exemplary embodiments, too.

As an option, there is a potting compound 8. The potting compound 8 can be of a transparent or also of a light-diffusing material. In particular, the potting compound 8 is of a silicone that could comprise particles to adjust the optical and/or mechanical properties thereof. The potting compound 8 can completely encase the light-emitting semiconductor chips 3, the molding compound 4 and the through connections 7. Further, the planar interconnects 5 can completely be covered by the optional potting compound 8.

The exemplary embodiment of FIG. 2 essentially corresponds to the exemplary embodiment of FIG. 1. However, the potting compound 8 comprises a phosphor 81. For example, the phosphor 81 comprises YAG:Ce to produce yellow light from blue light. Hence, the semiconductor device 1 can emit white light, composed of blue light from the light-emitting semiconductor chips 3 and of yellow light from the phosphor 81.

As a further option, the conductor tracks 23a, 23b of the same type at the two main sides 21, 22 can be electrically separated from one another. Thus, it might be possible to supply the light-emitting semiconductor chips 3 on one of the main sides 21, 22 independently of the light-emitting semiconductor chips 3 on the other main side 22, 21. To achieve this, it might be sufficient to have the conductor tracks 23a not directly connected to each other, but there could be an electrical short between the electrical termination connection surfaces 6b on the cathode side, for example.

According to the top view shown in FIG. 3, the light-emitting semiconductor chips 3 could be arranged along a straight line. However, an arrangement of the light-emitting semiconductor chips 3 in more than one line could also be realized, compare FIG. 4.

Moreover, in FIG. 4 it is illustrated that the terminal connection surfaces 6 could be located at just one end of the substrate 2. However, preferably the terminal connection surfaces 6 are located on both ends of the substrate as illustrated in FIG. 3.

According to the exemplary embodiment as shown in FIG. 5, the terminal connection surfaces 6 may not be centrally located at the ends of the substrate 2 but could be located in corner regions. Moreover, it is possible that the light-emitting semiconductor chips are electrically connected in a zigzag-like manner.

As a further option, in FIG. 5 it is illustrated that there can be first light-emitting semiconductor chips 3a and second light-emitting semiconductor chips 3b. For example, by means of the first light-emitting semiconductor chips 3a, blue light is produced. By means of the second light-emitting semiconductor chips, for example red light can be produced. By such an arrangement, an increased color rendering index can be achieved when a phosphor to produce yellow light is used. For example, there are fewer second light-emitting semiconductor chips 3b than first light-emitting semiconductor chips 3a.

In FIGS. 1 and 2, the light-emitting semiconductor chips 3 are electrically connected in parallel. Contrary to that, the light-emitting semiconductor chips 3 are electrically connected in series according to the exemplary embodiment of FIG. 6. Thus, the light-emitting semiconductor chips 3 are located on the electrical connection areas 24 which might be expanded. The through connections 7 could also be located on the connection areas 24 for the light-emitting semiconductor chips 3. Thus, the electrical contact of the radiation exit side 30 of a preceding light-emitting semiconductor chip 3 is connected by means of the planar electrical interconnect 5 and by means of the assigned electrical through connection 7 to the following electrical connection area 24 for the next light-emitting semiconductor chip 3 along the series connection.

Contrary to what is shown in FIG. 6, there could be just one series connection that extends from the first main side 21 to the second main side 22. This can be realized, for example, by an electrical through connection through the substrate 2, not shown.

As is possible in all other exemplary embodiments, the electrical contacts of the light-emitting semiconductor chips 3 need not be on different main sides of the light-emitting semiconductor chips 3. In particular, both electrical contacts could be located at the light exit side 30 facing away from the substrate 2. Thus, there could be two planar interconnects 5 for each one of the light-emitting semiconductor chips 3 in this case.

In FIGS. 7 to 10, further cross-sectional views are illustrated. The cross-sections in FIGS. 1, 2 and 6 are along a longitudinal direction, the cross-sections in FIGS. 7 to 10 are along a cross direction, that is along a plane perpendicular to the projection planes of FIGS. 1, 2 and 6.

FIG. 7 shows that there are two molding compounds 4 which are limited in each case to the respective main side 21, 22. The optional potting compound 8 can completely encase the other components of the semiconductor device 1, when seen in cross-section. Thus, in cross-section the semiconductor device 1 can be approximately of rectangular or square shape.

In FIG. 8 it is illustrated that there is only one molding compound 4 that extends in one piece over the first and the second main sides 21, 22 of the substrate 2. There could be two potting compounds 8 that might include the phosphor 81. Each of the potting compounds 8 is located over the respective main side 21, 22 of the substrate 2. The potting compound 8 could have a constant or a nearly constant layer thickness.

According to FIG. 7, the planar interconnect 5 is located centrally at the light-emitting semiconductor chips 3. This is not necessary as shown in FIG. 8 wherein the planar interconnects 5 could be located at an edge of the semiconductor chips 3, that is, seen in top view onto the main sides 21, 22, in a corner region of the light-emitting semiconductor chips 3.

In FIG. 9 it is illustrated that the light-emitting semiconductor chips 3 might be mounted on the substrate 2 eccentrically. However, the light-emitting semiconductor chips 3 can be mounted point symmetrically when seen in the cross-section of FIG. 9.

As an option, the potting compound 8 could be limited, or essentially limited, to the light exit sides 30 of the light-emitting semiconductor chips 3. The potting compound 8 might thus have a lens-like shape. Other than shown in FIG. 9, the potting compounds 8 can also have a constant or nearly constant layer thickness.

In FIG. 10 it is illustrated that both the molding compound 4 as well as the potting compound 8 can be of one piece. The planar interconnects 5 can be located eccentrically on the light-emitting semiconductor chips 3 in a mirror symmetric manner with respect to the substrate 2, contrary to what is illustrated in FIG. 8.

To produce the dual-sided LED emitter filaments 1 as illustrated in connection with FIGS. 1 to 10, the following method steps may be used:

a) die attach to attach the LED chips 3 and the via chips 7 to the substrate 2 with circuitry on one side,

b) snap cure to ensure that the chips 3, 7 are attached to the substrate 2,

c) flip over to attach the LED chips and via chips 3, 7 on the other side of the substrate 2 with circuitry,

d) die attach curing,

e) molding the molding compound 4 to create a surface for the planar interconnects 5,

f) lithography,

g) dielectric layer build-up, for example including resist deposition and resist exposure,

h) metallization build-up to form the planar interconnects 5,

i) apply solder resist, and

j) apply the potting compound which could be of clear fashion or could contain the at least one phosphor.

The components shown in the figures follow, unless indicated otherwise, preferably in the specified sequence directly one on top of the other. Layers which are not in contact in the figures are preferably spaced apart from one another. If lines are drawn parallel to one another, the corresponding surfaces are preferably oriented parallel to one another. Likewise, unless indicated otherwise, the positions of the drawn components relative to one another are correctly reproduced in the figures.

The invention described here is not restricted by the description on the basis of the exemplary embodiments. Rather, the invention encompasses any new feature and also any combination of features, which includes in particular any combination of features in the patent claims, even if this feature or this combination itself is not explicitly specified in the patent claims or exemplary embodiments.

### LIST OF REFERENCE SIGNS

1 optoelectronic semiconductor device
2 substrate
21 first main side of the substrate
22 second main side of the substrate
23 internal electrical conductor track
24 electrical connection area
3 light-emitting semiconductor chip
30 light exit side
4 molding compound
40 top side of the molding compound
5 planar electrical interconnect
6 electrical terminal connection surface
7 electrical through connection
8 potting compound
81 phosphor

1. An optoelectronic semiconductor device comprising
a substrate with a first main side and a second main side,
a plurality of light-emitting semiconductor chips which are distributed over the first main side and over the second main side,
at least one molding compound that encloses the light-emitting semiconductor chips in a lateral direction and that levels with the light-emitting semiconductor chips in a direction away from the substrate, the at least one molding compound has at least one top side facing away from the substrate, and
a plurality of planar electrical interconnects that run at least partly on the at least one top side and that electrically connect the light-emitting semiconductor chips on their radiation exit sides facing away from the substrate.

2. The optoelectronic semiconductor device according to claim 1,
which is fashioned as a filament so that a length of the optoelectronic semiconductor device exceeds a width thereof by at least a factor of five,
wherein electrical terminal connection surfaces to externally contact the optoelectronic semiconductor device are located solely at one end or at two opposing ends of the substrate.

3. The optoelectronic semiconductor device according to claim 2,
wherein at least one of the electrical terminal connection surfaces is arranged on the first main side and at least one of the electrical terminal connection surfaces is arranged on the second main side.

4. The optoelectronic semiconductor device according claim 1,
wherein the substrate comprises electrical connection areas on the first main side and on the second main side and comprises internal electrical conductor tracks that run to the connection areas,
wherein the light-emitting semiconductor chips are mounted on the connection areas.

5. The optoelectronic semiconductor device according to claim 4,
further comprising electrical through connections that run through the at least one molding compound,
wherein the electrical through connections are placed on the connection areas and electrically connect the connection areas with the corresponding planar electrical interconnects.

6. The optoelectronic semiconductor device according to claim 5,
wherein the electrical through connections are formed by via chips or by metallizations.

7. The optoelectronic semiconductor device according to claim 1,
wherein at least some of the light-emitting semiconductor chips are electrically connected in parallel.

8. The optoelectronic semiconductor device according to claim 7,
wherein all light-emitting semiconductor chips on the first main side are electrically connected in a first electrical parallel connection and all light-emitting semiconductor chips on the second main side are electrically connected in a second electrical parallel connection,
wherein the first and the second parallel connection can be electrically connected independently of one another.

9. The optoelectronic semiconductor device according to claim 1,
comprising two molding compounds, each molding compound is limited to one of the main sides of the substrate,
wherein each molding compound encloses all of the light-emitting semiconductor chips on the respective main side of the substrate.

10. The optoelectronic semiconductor device according to claim 1,
comprising exactly one molding compound which continuously extends to the first and to the second main side of the substrate, all of the light-emitting semiconductor chips are enclosed in the molding compound.

11. The optoelectronic semiconductor device according to claim 1,
further comprising at least one potting compound which covers the light-emitting semiconductor chips and the at least one molding compound.

12. The optoelectronic semiconductor device according to claim 11,
wherein the at least one potting compound comprises at least one phosphor,
wherein the light-emitting semiconductor chips together with the phosphor are configured to produce white light.

13. The optoelectronic semiconductor device according to claim 1,
wherein the substrate has a thermal conductivity of at least 25 W/(m·K),
wherein a mean thickness of the substrate is between 0.2 mm and 2 mm inclusive.

14. The optoelectronic semiconductor device according to claim 1,
which is mechanically flexible so that the optoelectronic semiconductor device can reversibly be bent with a radius of curvature of 2 cm or less.

15. A method for producing an optoelectronic semiconductor device according to claim 1, comprising the following steps in the stated order:
providing the substrate,
attaching the respective light-emitting semiconductor chips at the first main side,
attaching the respective light-emitting semiconductor chips at the second main side,
molding the molding compound, and
applying the planar electrical interconnects.

16. The method according to claim 15,
wherein the molding compound (4) is formed by foil-assisted molding,
wherein between the steps of attaching the respective light-emitting semiconductor chips to the first main side and to the second main side, in a snap curing step the light-emitting semiconductor chips at the first main side are preliminarily connected to the first main side.

17. An optoelectronic semiconductor device comprising
a substrate with a first main side and a second main side,
a plurality of light-emitting semiconductor chips which are distributed over the first main side and over the second main side,
at least one molding compound that encloses the light-emitting semiconductor chips in a lateral direction and that levels with the light-emitting semiconductor chips in a direction away from the substrate, the at least one molding compound has at least one top side facing away from the substrate, and
a plurality of planar electrical interconnects that run at least partly on the at least one top side and that electrically connect the light-emitting semiconductor chips on their radiation exit sides facing away from the substrate,
wherein
the substrate comprises electrical connection areas on the first main side and on the second main side and comprises internal electrical conductor tracks that run to the connection areas, the light-emitting semiconductor chips are mounted on the connection areas, and
the internal electrical conductor tracks are not accessible from an exterior of the semiconductor device so that the light-emitting semiconductor chips on one of the main sides can be supplied with current independently of the light-emitting semiconductor chips on the other main side.
